(19) United States
(12) Patent Application Publication
(10) Pub. No.: US 2015/0108568 A1
(43) Pub. Date: Apr. 23, 2015

(54) SEMICONDUCTOR STRUCTURE WITH HIGH ENERGY DOPANT IMPLANTATION

(71) Applicant: Vishay-Siliconix, Santa Clara, CA (US)

(72) Inventors: Kyle TERRILL, Santa Clara, CA (US); Lingpeng GUAN, San Jose, CA (US)

(73) Assignee: Vishay-Siliconix, Santa Clara, CA (US)

(21) Appl. No.: 14/058,933

(22) Filed: Oct. 21, 2013

(51) Int. Cl. H01L 29/78; H01L 29/08; H01L 29/66

(52) U.S. Cl. CPC H01L 29/7813; H01L 29/66734; H01L 29/086
USPC 257/331; 438/271

(57) ABSTRACT

A semiconductor device has an epitaxial layer grown over a substrate, each having a first dopant type. A structure disposed within the epitaxial layer has multiple trenches, each of which has a gate and a source electrode disposed within a shield oxide matrix. Multiple mesas each isolate a pair of the trenches from each other. A body region with a second dopant type is disposed above the epitaxial layer and bridges each of the mesas. A region of elevated concentration of the first dopant type is implanted at a high energy level between the epitaxial layer and the body region, which reduces resistance spreading into a channel of the device. A source region having the first dopant type is disposed above the body region.

Embodiments of the present invention relate to semiconductors. More particularly, an example embodiment of the present invention relates to fabricating a split gate MOSFET device.

### BACKGROUND

A metal oxide semiconductor field effect transistor (MOSFET) comprises a semiconductor device, which finds utility in the switching and amplification of electronic signals. A power MOSFET is capable of switching significant power levels. Some power MOSFETs are structured vertically. Relative to devices with more lateral structures, vertical power MOSFETs have higher effective channel areas, which can allow conduction of substantial current levels and maintain high blocking voltages.

Power MOSFETs have fast commutation speeds (e.g., with which they switch between conductivity states). Power MOSFET gates may be driven without drawing significant power. Combined with their robust current handling and the ease with which they may be paralleled electrically, fast switching and low gate driving power draw make MOSFETs useful in power handling applications, such as direct current (DC) power supplies. Power MOSFETs may be used for example in DC-DC power conversion.

With reference to semiconductor technologies generally and in particular, as used herein, the letter ‘n’ may refer to an n-type dopant material (dopant) and the letter ‘p’ may refer to a p-type dopant. As used herein, a plus sign ‘+’ and a minus sign ‘−’ may represent, respectively, a relatively high or relatively low concentration of the dopants.

The term ‘channel’ is used herein in relation to current moving therein, within a MOSFET device, from a source connection to a drain connection. As channels may comprise an n-type semiconductor material or a p-type semiconductor material; MOSFETs may be characterized respectively as an n-channel device or a p-channel device.

As used herein in relation to a semiconductor structure or device, the term ‘trench’ refers to a solid vertical structure disposed beneath a surface of a substrate and adjacent to a channel of a MOSFET. The trench structure has a complex composition, which varies in relation to the substrate. For example, the gate and source electrodes of a MOSFET may be disposed in a trench thereof.

Trench semiconductor devices comprise a mesa structure independent of their trenches, which each separate at least two portions (e.g., each one half) of two adjacent structural trenches. A trench may thus be formed by etching a void in a semiconductor structure, which is longer than it is wide and/or deep, and then filling the formed void with the composition material of the solid vertical structure.

It is to be appreciated that the term “trench” may sometimes take an alternate or additional meaning in some arts relating to semiconductors, which refers to the void itself, and may thus conform to a more conventional or lay usage of the term. Unless specifically mentioned otherwise in a particular use herein however, the term “trench” refers to the solid material structure with which a previously etched void may be filled.

Electrons (with their negative charge) are known to transport current somewhat faster and more efficiently in some semiconductor substances and/or structures than holes (with their positive charge). As robust current handling comprises a significant feature thereof, many power MOSFETs are configured and/or fabricated such that electrons comprise their majority carrier.

Thus, some power MOSFETs have structures in which an epitaxial layer is grown over a semiconductor substrate, which comprises a substance doped with a concentration of N-type dopants in excess of that of the N-type dopants in the epitaxial layer. The drain of the MOSFET may be electrically coupled to a drain electrode, which contacts a lower, planar surface of its substrate layer. A body layer, doped with p-type dopants (thus referred to as ‘P-body’) is disposed over the epitaxial layer. The channel regions form in the P-body, e.g., adjacent horizontally to a region of the trenches in which the gate electrode may be disposed.

DC-DC converters typically comprise a high voltage side control MOSFET and a low voltage side synchronous MOSFET. In this context, the terms ‘high’ and ‘low’ refer to two (2) different DC voltage levels within the converter and are used in relation to each other. Split gate and/or trench structure technologies are used to optimally minimize conduction and switching loss in control MOSFETs. Minimizing the on-state resistance, e.g., the resistance between the source and drain of a MOSFET while it is in its conducting state (‘Rdson’) reduces conduction and switching loss.

As miniaturization progresses, MOSFETs with pitch size reductions below one micrometer (1 μm), such as to sizes of between 0.8 μm and 0.6 μm and smaller are being made. For example, U.S. Pat. No. 7,375,029 B2 to Poelzl (“Poelzl”) describes semiconductor structures that include trenches isolated from one another by mesa regions in a semiconductor body with contact holes fabricated therein, in which tolerances are kept “as small as possible.” (Poetzl, col. 1/II.50-54.)

While the size of control MOSFETs thus fabricated becomes smaller, the size of their corresponding mesa regions is reduced. With such small mesa regions, spreading of resistances may occur. For example, conventional split gate and trench MOSFET structures may have a narrow drift region with a low dopant concentration under its body region (e.g., p-body), within its epitaxial layer. This narrow region of low dopant concentration comprises a significant contribution to the overall Rdson of a MOSFET.

Resistance may spread from this narrow region of low dopant concentration due to the small dimensions of the mesa region, thermal diffusion of dopants in the vicinity thereof or between the regions, and/or the effect of small overlaps of trench polysilicon beyond the horizontal extent of the P-body. Moreover, the effect of this spreading resistance may be exacerbated by the fact that current flow through the MOSFET must spread out from the channel region into the region below the P-body. Minimizing the effects of resistance spread in conventional MOSFETs however may degrade their breakdown voltage characteristics.

Approaches described in this section could, but have not necessarily been conceived or pursued previously. Unless otherwise indicated, neither approaches described in this section, nor issues identified in relation thereto, are to be assumed as recognized in any prior art merely by inclusion therein.

### SUMMARY

It would be useful to minimize spreading of resistance in a semiconductor structure such as a MOSFET, which could relate for example to small dimensions of the mesa region thereof, thermal diffusion of dopants in the vicinity thereof or between the regions, and/or the effect of small overlaps of trench polysilicon beyond the horizontal extent of the P-body. It would also be useful to deter compounding or exacerbating effects of such spreading resistance, which may relate for example to current flow patterns through the MOSFET such as a spread of current flow outward from the channel region below the P-body region. Further, it would be useful to minimize resistance spread and its effects without significant degradation of the breakdown voltage of the MOSFET.

An embodiment of the present invention relates to a semiconductor structure fabricated with a high energy dopant implantation. In an example embodiment of the present invention, a semiconductor device comprises an epitaxial layer grown over a semiconductor substrate, each comprising a first type of dopant. A structure is disposed within the epitaxial layer. The structure comprises multiple trenches. Each of the trenches comprises a gate electrode and a source electrode, which are disposed within a shield oxide matrix. Further, the structure comprises multiple mesas, each of which isolates a first of the multiple trenches from a second of the trenches. A body region bridges each of the multiple mesas. The body region is disposed above the epitaxial layer and comprises a second type of dopant.

In an example embodiment of the present invention, a region of elevated concentration of the first type of dopant is implanted at a high energy level and disposed between the epitaxial layer and the body region. Example embodiments may be implemented in which the high energy level comprises an energy level of five hundred thousand electron Volts (500 keV) to 1,000 keV, inclusive.

A source region comprising the first type of dopant and disposed above the body region.

In an example embodiment of the present invention, the gate electrode is disposed above the source electrode within each of the multiple trenches. Further, each of the trenches comprises a portion of the shield oxide matrix, which is disposed between a lower surface of the gate electrode and an upper surface of the source electrode.

In an example embodiment, the semiconductor substrate comprises silicon. The substrate is doped with a first concentration of the first type of dopant, the epitaxial layer is doped with a second concentration of the first type of dopant, and the first dopant concentration exceeds the second dopant concentration. The first type of dopant differs from the second type of dopant. For example, the first type of dopant may comprise an n-type dopant and the second type of dopant may comprise a p-type dopant.

In an example embodiment, the epitaxial layer comprises a first semiconducting substance and the gate electrode and/or the source electrode comprises a second semiconducting substance. With an epitaxial layer of monocrystalline or similar silicon for example, the second semiconducting substance may comprise polycrystalline silicon.

In an example embodiment of the present invention, the device comprises a gate electrically coupled to the gate electrode, in which the gate is self-aligned in relation to the source region. The device may comprise a MOSFET. An example embodiment relates to a power MOSFET with a vertical channel and split-gate trench arrangement. Example embodiments of the present invention also relate to methods for fabricating a semiconductor device and to electronic products such as MOSFETs, which are produced by such processes.

An example embodiment is described below in relation to fabricating a split gate trench power MOSFET high energy dopant implantation. In an example embodiment, a high dosage n+ dopant is implanted at a high energy level, which reduces resistance in a region of the electronic device and concomitantly, the Rdson of the device or degrading its breakdown voltage characteristics.

Thus, an example embodiment of the present invention minimizes the spread of resistance in a semiconductor structure such as a MOSFET, which could otherwise arise in relation to small dimensions of the mesa region thereof, thermal diffusion of dopants in the vicinity thereof or between the regions, and/or an effect arising in relation to small overlaps of trench polysilicon beyond the horizontal extent of the P-body. An example embodiment deters compounding or exacerbating effects of such spreading resistance, which may arise in relation to current flow patterns through the MOSFET (e.g., a spread of current flow outward from the channel region below the P-body region). An example embodiment minimizes the spread of resistance and effects thereof, without significant degradation of the breakdown voltage of the MOSFET.

### BRIEF DESCRIPTION OF THE DRAWINGS

An embodiment of the present invention relates to a semiconductor structure fabricated with a high energy dopant implantation. The accompanying drawings below comprise a part of the specification of example embodiments of the present invention and are used for explaining features, elements and attributes thereof. Principles of example embodiments are described herein in relation to each figure (FIG.) of these drawings, in which like numbers are used to reference like items, no particular scale is used (unless stated otherwise), and in which:

FIG. 1 depicts a portion of an example semiconductor device with a high energy dopant implantation, according to an embodiment of the present invention;

FIG. 2 depicts an example structure formed in fabricating a semiconductor, according to an embodiment of the present invention;

FIG. 3 depicts a comparison of example dopant concentrations;

FIG. 4 depicts an example structure in fabricating a semiconductor device, according to an embodiment of the present invention;

FIG. 5 depicts an example structure formed in fabricating a semiconductor device, according to an embodiment of the present invention;

FIG. 6 depicts an example structure formed in fabricating a semiconductor device, according to an embodiment of the present invention;

FIG. 7 depicts an example structure formed in fabricating a semiconductor device, according to an embodiment of the present invention; and

FIG. 8 depicts a flowchart for an example process with which a semiconductor device is fabricated using high energy doping, according to an embodiment of the present invention.

### DESCRIPTION OF EXAMPLE EMBODIMENTS

An embodiment of the present invention relates to a semiconductor structure fabricated with a high energy dopant implantation. Reference will now be made in detail to implementations of the example embodiments as illustrated in the accompanying drawings. The same reference numbers will be used to the extent possible throughout the drawings and the following description to refer to the same or like items. It will be apparent to artisans of ordinary skill in technologies that relate to semiconductors however, that example embodiments of the present invention may be practiced without some of these specifically described details. Example embodiments of the present invention are described in relation to a split gate trench power MOSFET with a high energy dopant implantation.

For focus, clarity and brevity, as well as to avoid unnecessarily occluding, obscuring, obstructing or obfuscating features that may be somewhat more germane or relevant to, or significant in explaining example embodiments of the present invention, this description may avoid describing some well-known processes, structures, components and devices in exhaustive detail. Artisans of ordinary skill in semiconductor related technologies should realize that the following description is made for purposes of explanation and illustration and is not intended to be limiting in any way. On the contrary; other embodiments should readily suggest themselves to artisans of such skill in relation to the example features and elements described herein and any corresponding benefits such embodiments may achieve. An example embodiment of the present invention is described in relation to a split gate trench power MOSFET with a high energy dopant implantation.

While embodiments are described herein with reference to example power MOSFETs and slit gate trench semiconductor devices and structures, it should be appreciated that this is by way of illustration, example, clarity, brevity and simplicity of description. Moreover, artisans of ordinary skill in arts relating to semiconductor technologies should especially appreciate and understand that the scope of embodiments of the present invention thus covers semiconductor devices more generally than described herein and more particularly, to other transistors or devices that are not dissimilar thereto.

An embodiment of the present invention relates to a semiconductor structure fabricated with a high energy dopant implantation. A semiconductor device has an epitaxial layer grown over a substrate, each having a first dopant type. A structure disposed within the epitaxial layer has multiple trenches, each of which has a gate and a source electrode disposed within a shield oxide matrix. Multiple mesas each isolate a pair of the trenches from each other. A body region with a second dopant type is disposed above the epitaxial layer and bridges each of the mesas. A region of elevated concentration of the first dopant type is implanted at a high energy level between the epitaxial layer and the body region, which reduces resistance spreading into a channel of the device. A source region having the first dopant type is disposed above the body region. An example embodiment is described below.

Example Semiconductor Device

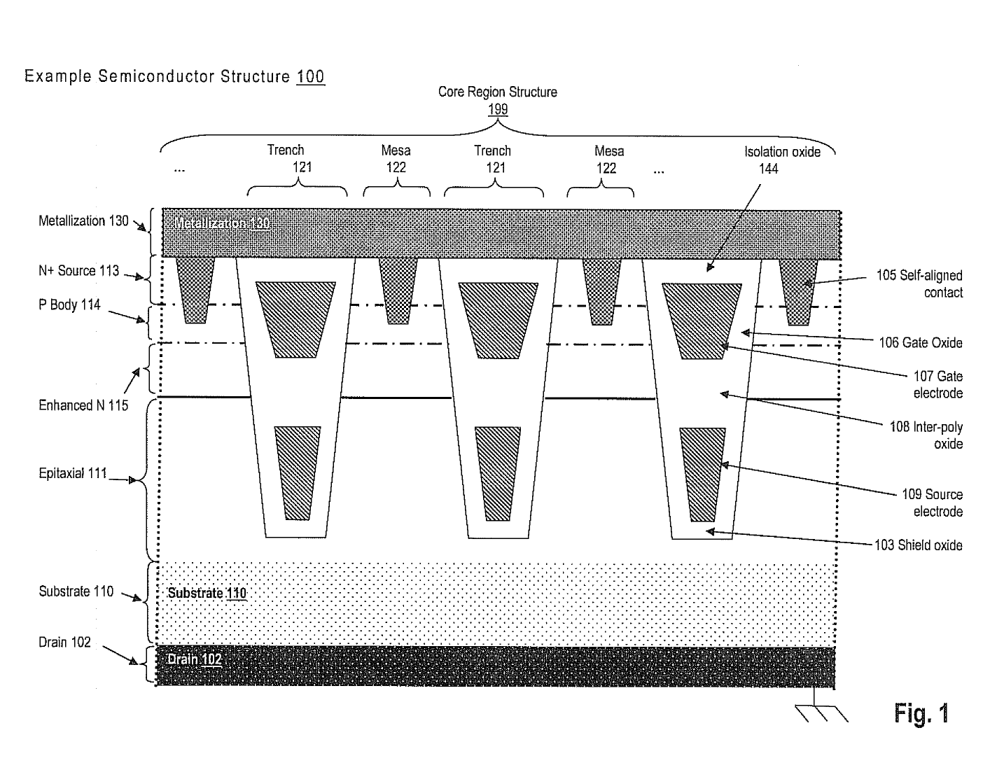

FIG. 1 depicts a portion of an example semiconductor device 100, according to an embodiment of the present invention. The depicted portion may comprise a core area 199 of the device in an electronic product such as a split gate power MOSFET. FIG. 1 depicts a side view of a cross-section of the core area, which may extend further from each side. It should be appreciated that, beside the horizontal width and vertical height depicted, the example device 100 also has a depth and thus, that the cross section of core section 199 further represents implicitly a not dissimilar third dimension.

Device 100 comprises a semiconductor substrate 110 such as silicon. An example embodiment may be implemented in which the substrate 110 also comprises a first type of dopant (e.g., n type). An epitaxial layer 111 is grown over the substrate 110. The epitaxial layer 111 also comprises silicon, which also doped with the first dopant type. The concentration of the dopant in the substrate exceeds the level of the dopant in the epitaxial layer, which is disposed above it. A drain electrode of the device is disposed in electrical contact over a lower surface of the substrate 110.

A structure is disposed within the epitaxial layer 111. The structure comprises a plurality (e.g., multiplicity) of trenches 121 and a plurality of mesas 122. Each of the mesas 122 isolates one (e.g., a first) of the multiple trenches 121 from another (e.g., second) of the multiple trenches 121. The trenches 121 each fill voids, which had been formed within the epitaxial layer 111 upon its growth. Thus, an outer surface of each of the trenches 121 is disposed against a portion of the epitaxial layer 111 that had, e.g., comprised an inner surface of one of the voids.

Each of the trenches 121 comprises a gate electrode 107 and a source electrode 109 disposed within an oxide matrix, which shields the electrodes from the outer surface of each of the trenches 121. In an example embodiment, the gate electrode 107 is disposed above the source electrode 109. Thus, a shield oxide 103 shields the source electrode 109 from a bottom and/or a lower portion of the outer surface of the trench 121 and an inter-electrode oxide shields a lower surface of the gate electrode 107 from an upper surface of the source electrode 109 near a middle portion of the trench 121.

In an example embodiment, the epitaxial layer 111 comprises a monocrystalline or similar first type of silicon. The gate electrode 107 and/or the source electrode 109 comprises a polycrystalline or similar second type of silicon, e.g., polysilicon (“poly”). A gate oxide 106 is grown around the outer surface of the gate electrode 107 with an annular aspect in relation to the vicinity of an upper portion of the trench 121. An isolation oxide 144, which fills the trench 121 to its top, is disposed over an upper surface of the gate electrode 107.

A body region 114 bridges each of the mesas 122. The body region 114 comprises silicon, which is doped with a second type, such as boron (B) and/or boron trifluoride (BF₃) of dopant and may be referred to herein as a p-body. In an example embodiment of the present invention, an elevated concentration of the n-type dopant has been implanted at a high energy level (e.g., 300-1000 kV) in an enhancement region 115, within an upper portion of the epitaxial layer. A source region 113, which comprises silicon doped with n type dopants, is disposed above each of the p-bodies 114.

A self aligned contact 105 for gating the channels of the device 100 that form within its mesas 122 overlaps at least a portion of an upper surface of the source regions 113. The self aligned contact 105 extends vertically through the source 113 into the p-body 114. The self aligned contact 105 may comprise one or more metallic substances or alloys (e.g., aluminum, tungsten, titanium). A metallization layer 130 comprising aluminum or another metal is disposed over an upper surface of the core structure 199 in contact with an upper surface of the sources 113.

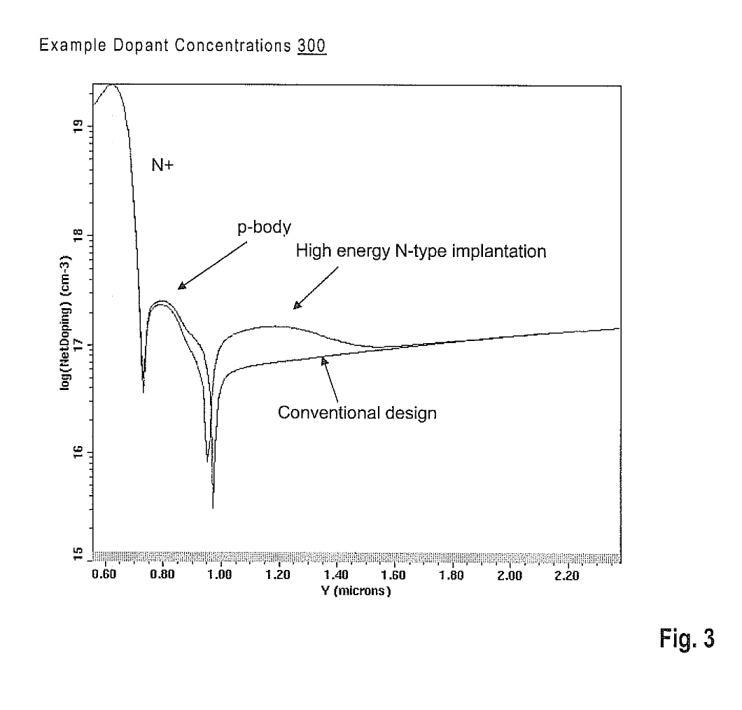

FIG. 3 depicts a comparison 300 of example dopant concentrations. The dopant concentrations are plotted over depth within the structure of a semiconductor device, e.g., as depicted in FIG. 1. The dopant concentration plot 301 represents a MOSFET implementation, which may be fabricated according to an example embodiment. The dopant concentration plot 302 typifies conventionally fabricated MOSFETs. In relation to conventional plot 302, example plot 301 shows heightened concentrations of N-type dopants over depths that span approximately 0.75 μm to 1.50 μm or more, which correspond to the areas 115 of heightened n+ type dopant concentration.

The Rdson values corresponding to the dopant concentrations 302 plotted for the conventional MOSFET exceed the Rdson values corresponding to the dopant concentration curve 301 plotted for the MOSFET implementation fabricated according to an example embodiment, e.g., by approximately 20 percent. The high energy n+ type doping of an example embodiment of the present invention may thus improve the Rdson characteristics of semiconductor devices fabricated therewith.

Example Fabrication Process and Structures

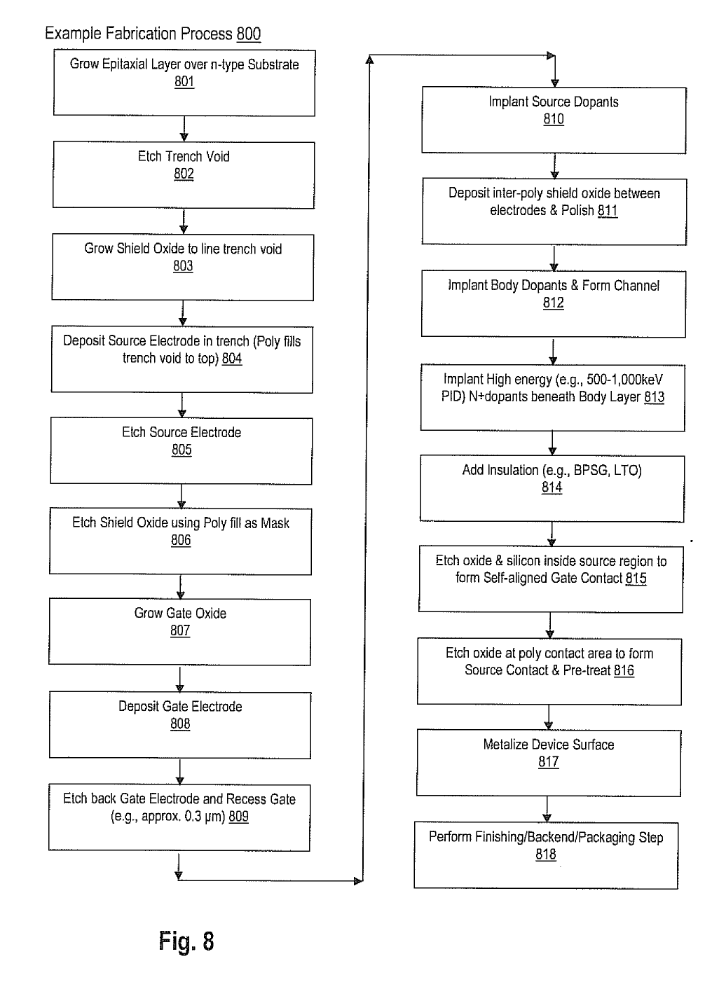

FIG. 8 depicts a flowchart for an example process 800 with which a semiconductor device is fabricated using high energy doping, according to an embodiment of the present invention. The high energy doping deter resistances from spreading in devices thus fabricated. A variety of semiconductor products relating to power MOSFETs (but not limited thereto) may thus be fabricated. For example, the devices may comprise a split-gate and/or trench structure.

In step 801, the epitaxial layer 111 is grown over a semiconductor substrate 110, such as silicon. An example embodiment may be implemented in which an n-type epitaxial layer 111 is grown over a n+ doped substrate 110. Thus, the epitaxial layer 111 is doped with an n-type dopant at a concentration level that is low (e.g., light) in relation to the silicon substrate 110, which is doped with a relatively high (e.g., heavy) n-type dopant.

In step 802, a void with a depth of approx. 0.5 μm-2 μm, is etched into the epitaxial layer 111. For example, thermal oxidation grows a hard mask oxide on the upper surface of the epitaxial layer 111 and photolithography leaves photoresist in areas outside the regions to be occupied by the trenches 121. Plasma etching etches the trench voids removing the hard mask oxide and the Silicon from the trench regions. As the voids are etched, the remaining un-etched material forms the mesas 122, which separate each of the trench voids from each other.

After removing the photoresist and the hard oxide mask, the shield oxide matrix is grown or deposited, e.g., with chemical vapor deposition (CVD) within the etched void in step 803. The shield oxide 103 comprises an electrical insulator and is deposited to line the trench void.

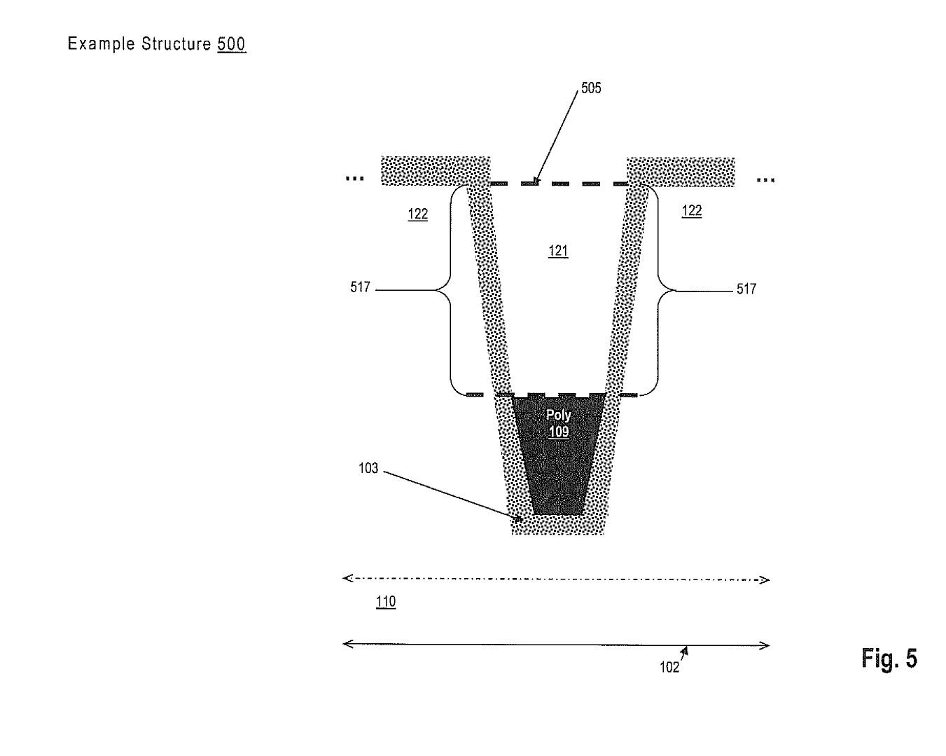

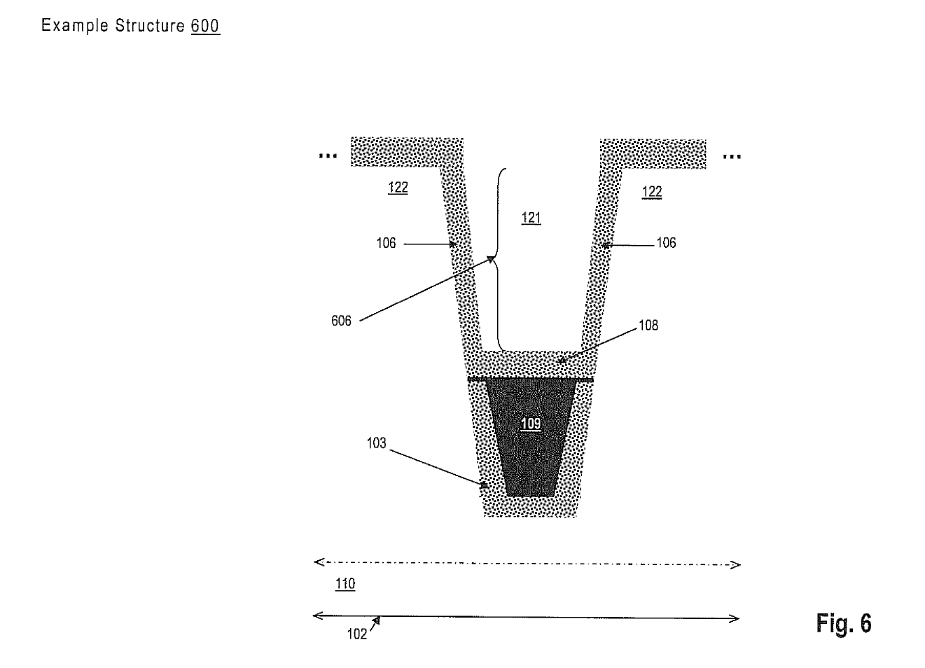

FIG. 5 and FIG. 6 depict respectively example structures 500 and 600 formed in fabricating a semiconductor device, according to an embodiment of the present invention. In step 804, doped polysilicon material, from which a source electrode 109 will be formed, is deposited within the trench void. The doped polysilicon fills the trench void to an upper extent (e.g., opening) 505 thereof.

The shield oxide matrix electrically insulates and physically separates the polysilicon in the trench from the outer surface of the trench void (e.g., the inner surface of the void, which marks the outer surface of the mesa). The polysilicon, with the rest of the upper surface of the core structure, is planarized. Photolithography leaves photoresist over the area in which contacts will be made to the source electrode.

In step 805, etching is performed. For example, plasma etching etches a portion 606 (e.g., approx. 0.9 μm) of polysilicon material back from the upper region of the trench 121 to form the source electrode 109. After cleaning the wafer, photolithography leaves photoresist in areas outside a region 517 in which thick side wall oxide will be removed. Using the polysilicon in region 517 as a mask, wet etching etches the oxide in the region 517. Upon the removal of the side wall oxide from region 517, the wafer is cleaned. In step 806, the gate oxide 106 is grown.

In step 808, a second doped polysilicon region is disposed over the gate oxide to form the gate electrode, the surface of which is then be planarized. Photolithography leaves photoresist over the gate electrode for those areas in which contacts will be made to the gate electrode and in step 809, a portion (e.g., approx. 0.2-0.3 μm) of the polysilicon material is etched back (e.g., with plasma etching) to recess the gate and the wafer is cleaned.

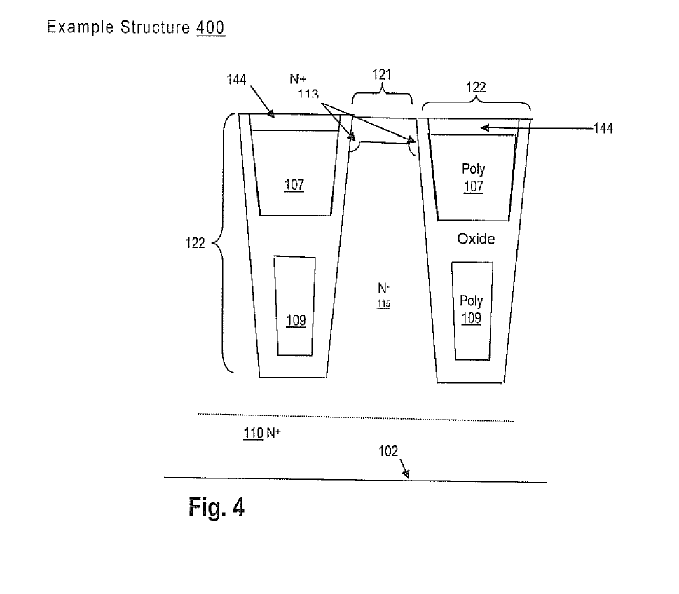

FIG. 4 depicts an example structure 400 in fabricating a semiconductor device, according to an embodiment of the present invention. In step 810, n+ dopants are implanted over the epitaxial layer 111 to form the source region 113. An example embodiment may be implemented wherein the n+ source 113 is implanted with angle implantation and annealed. The source 113 is thus disposed in an annular aspect in an upper portion of the mesas 122 in the vicinity of an upper portion of the gate electrode 107. In step 811, the isolation oxide 144 is deposited over the upper surface, which is then planarized, e.g., with chemical mechanical polishing (CMP).

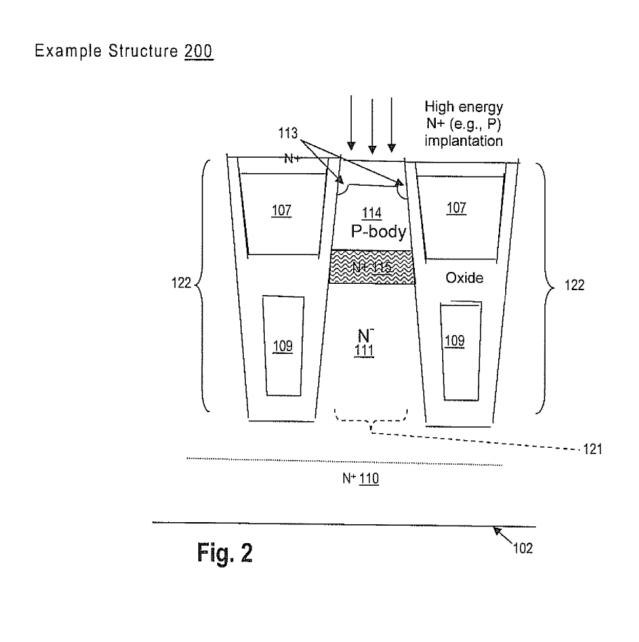

FIG. 2 depicts an example structure 200 formed in fabricating a semiconductor, according to an embodiment of the present invention. In step 812, p-type dopant implantation forms the P-body 114, which is disposed over the n− doped epitaxial silicon layer 111. In step 813, additional n+ dopants (e.g., P, B and/or BF₃) are implanted beneath the p-body 114 at a high energy level (e.g., 500 keV-1,000 keV). In an example embodiment of the present invention, their high energy implantation forms an area 115 with an elevated n+ doping concentration, which significantly exceeds the n− doping level of the n− epitaxial layer 111 below. An example embodiment thus minimizes the spread of resistance in the conduction channel of the MOSFET.

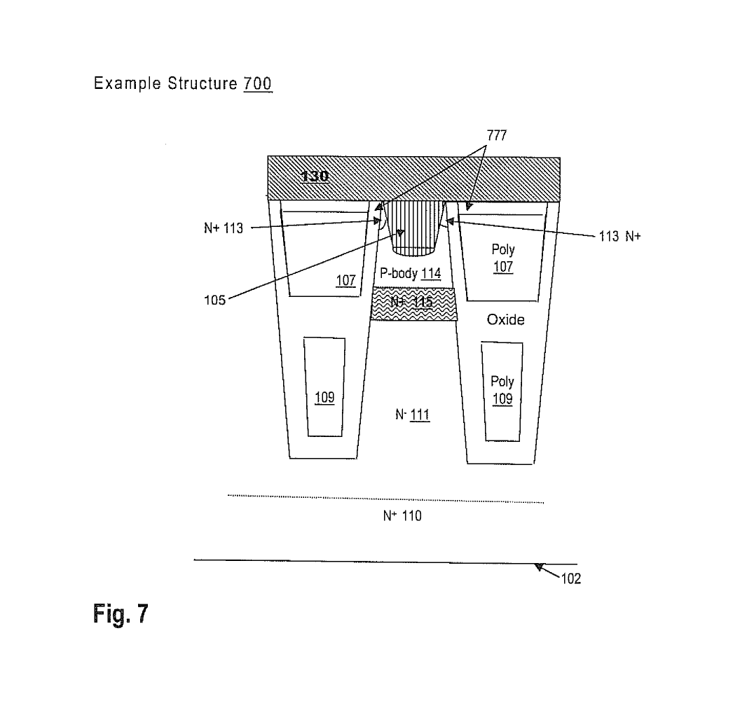

In step 814, an insulating layer comprising low temperature [silicon] oxide (LTO) and/or borophosphosilicate glass (BPSG) is deposited. FIG. 7 depicts an example structure 700 formed in fabricating a semiconductor device, according to an embodiment of the present invention. Photolithography leaves photoresist at the region outside the source contact area. In step 815, plasma etching etches oxide and silicon from inside the source region 114 to form the self-aligned contact 105. In step 816, oxide is etched in the area of the polysilicon to form source and gate electrode contacts 777.

The surface of the wafer is cleaned and pre-treated (e.g., with warm hydrofluoric acid) and in step 817, the metallization layer 130 comprising one or more metallic substances or alloys (e.g., aluminum, titanium, tungsten, etc.) is deposited on the upper surface. After metalizing the surface, one or more backend, packaging and/or finishing processes may be performed to complete the fabrication of a MOSFET or other semiconductor device product. The metallization of the wafer surface and/or the backend, packaging or finishing processes may proceed according to a variety of techniques familiar to artisans skilled in fields relating to semiconductors.

Thus, an example embodiment of the present invention relates to a semiconductor device, which comprises an epitaxial layer grown over a semiconductor substrate, each comprising a first type of dopant. A structure is disposed within the epitaxial layer. The structure comprises multiple trenches. Each of the trenches comprises a gate electrode and a source electrode, which are disposed within a shield oxide matrix. Further, the structure comprises multiple mesas, each of which isolates a first of the multiple trenches from a second of the trenches. A body region bridges each of the multiple mesas. The body region is disposed above the epitaxial layer and comprises a second type of dopant.

In an example embodiment of the present invention, a region of elevated concentration of the first type of dopant is implanted at a high energy level and disposed between the epitaxial layer and the body region. Example embodiments may be implemented in which the high energy level comprises an energy level of 300 keV to 1,000 keV, inclusive.

A source region comprising the first type of dopant and disposed above the body region.

In an example embodiment of the present invention, the gate electrode is disposed above the source electrode within each of the multiple trenches. Further, each of the trenches comprises a portion of the shield oxide matrix, which is disposed between a lower surface of the gate electrode and an upper surface of the source electrode.

In an example embodiment, the semiconductor substrate comprises silicon. The substrate is doped with a first concentration of the first type of dopant, the epitaxial layer is doped with a second concentration of the first type of dopant, and the first dopant concentration exceeds the second dopant concentration. The first type of dopant differs from the second type of dopant. For example, the first type of dopant may comprise an n-type dopant and the second type of dopant may comprise a p-type dopant.

In an example embodiment, the epitaxial layer comprises a first semiconducting substance and the gate electrode and/or the source electrode comprises a second semiconducting substance. With an epitaxial layer of mono-crystalline or similar silicon for example, the second semiconducting substance may comprise polycrystalline silicon.

In an example embodiment of the present invention, the device comprises a gate electrically coupled to the gate electrode, in which the gate is self-aligned in relation to the source region. The device may comprise a MOSFET. An example embodiment relates to a power MOSFET with a vertical channel and split-gate trench arrangement. Example embodiments of the present invention also relate to methods for fabricating a semiconductor device and to electronic products such as MOSFETs, which are produced by such processes.

Example embodiments of the present invention are thus described in relation to a semiconductor structure with a high energy dopant implantation. An example embodiment of the present invention is described above in relation to a process for fabricating a semiconductor device such as a split gate trench power MOSFET with the high energy dopant implantation. In the foregoing specification, example embodiments of the present invention are described with reference to numerous specific details that may vary between implementations. Thus, the sole and exclusive indicator of that, which embodies the invention, and is intended by the Applicants to comprise an embodiment thereof, is the set of claims that issue from this application, in the specific form in which such claims issue, including any subsequent correction.

Definitions that are expressly set forth in each or any claim specifically or by way of example herein, for terms contained in relation to features of such claims are intended to govern the meaning of such terms. Thus, no limitation, element, property, feature, advantage or attribute that is not expressly recited in a claim should limit the scope of such claim in any way. The specification and drawings are, accordingly, to be regarded in an illustrative rather than a restrictive sense.

What is claimed is:

1. A semiconductor device, comprising:
an epitaxial layer grown over a semiconductor substrate, each comprising a first type of dopant;
a structure disposed within the epitaxial layer, the structure comprising:
a plurality of trenches, each of the trenches comprising a gate electrode and a source electrode disposed within a shield oxide matrix; and
a plurality of mesas, each of which isolates a first of the plurality of trenches from a second of the plurality of trenches;
a body region bridging each of the plurality of mesas, wherein the body region is disposed above the epitaxial layer and comprises a second type of dopant;
a region of elevated concentration of the first type of dopant, which is implanted between the epitaxial layer and the body region; and
a source region comprising the first type of dopant and disposed above the body region.

2. The device as recited in claim 1 wherein, within each of the plurality of trenches, the gate electrode is disposed above the source electrode and wherein each of the plurality of trenches further comprises a inter-poly oxide, which is disposed between a lower surface of the gate electrode and an upper surface of the source electrode.

3. The device as recited in claim 1 wherein the region of elevated concentration of the first type of dopant, is implanted at a high energy level, wherein the high energy level comprises at least one of at least three hundred thousand electron Volts (300 keV), in excess of 300 keV, or between 300 keV and 1,000 keV, inclusive.

4. The device as recited in claim 1 wherein the substrate is doped with a first concentration of the first type of dopant, wherein the epitaxial layer is doped with a second concentration of the first type of dopant, and wherein the first dopant concentration exceeds the second dopant concentration.

5. The device as recited in claim 1 wherein the first type of dopant differs from the second type of dopant.

6. The device as recited in claim 1 wherein first type of dopant comprises an n-type dopant and wherein the second type of dopant comprises a p-type dopant.

7. The device as recited in claim 1 wherein first type of dopant comprises a p-type dopant and wherein the second type of dopant comprises a n-type dopant.

8. The device as recited in claim 1 wherein the semiconductor substrate comprises silicon.

9. The device as recited in claim 1 wherein the epitaxial layer comprises a first semiconducting substance and wherein one or more of the gate electrode or the source electrode comprises a second semiconducting substance.

10. The device as recited in claim 9 wherein the second semiconducting substance comprises polycrystalline silicon.

11. The device as recited in claim 1, further comprising a gate electrically coupled to the gate electrode wherein the gate is self-aligned in relation to the source region.

12. A method for fabricating a semiconductor device, the method comprising:
growing an epitaxial layer grown over a semiconductor substrate, each of which comprises a first type of dopant;
assembling a structure disposed within the epitaxial layer, the structure comprising:
a plurality of trenches, each of the trenches comprising a gate electrode and a source electrode disposed within a oxide matrix; and
a plurality of mesas, each of which isolates a first of the plurality of trenches from a second of the plurality of trenches;
depositing a body region bridging each of the plurality of mesas, wherein the body region is disposed above the epitaxial layer and comprises a second type of dopant;
implanting, between the epitaxial layer and the body region, a region of elevated concentration of the first type of dopant; and
implanting a source region, comprising the first type of dopant.

13. The method as recited in claim 12 wherein, within each of the plurality of trenches, the gate electrode is disposed above the source electrode and wherein each of the plurality of trenches further comprises a inter-poly oxide, which is disposed between a lower surface of the gate electrode and an upper surface of the source electrode.

14. The method as recited in claim 12 wherein the region of elevated concentration of the first type of dopant, is implanted at a high energy level, which and comprises at least one of at least three hundred thousand electron Volts (300 keV), in excess of 300 keV, or between 300 keV and 1,000 keV, inclusive.

15. The method as recited in claim 12 wherein the substrate is doped with a first concentration of the first type of dopant, wherein the epitaxial layer is doped with a second concentration of the first type of dopant, and wherein the first dopant concentration exceeds the second dopant concentration.

16. The method as recited in claim 12 wherein the first type of dopant differs from the second type of dopant.

17. The method as recited in claim 12 wherein first type of dopant comprises an n-type dopant and wherein the second type of dopant comprises a p-type dopant.

18. The method as recited in claim 12 wherein first type of dopant comprises a p-type dopant and wherein the second type of dopant comprises a n-type dopant

19. The method as recited in claim 12 wherein the semiconductor substrate comprises silicon.

20. The method as recited in claim 12 wherein the epitaxial layer comprises a first semiconducting substance and wherein one or more of the gate electrode or the source electrode comprises a second semiconducting substance.

21. The method as recited in claim 20 wherein the second semiconducting substance comprises polycrystalline silicon.

22. The method as recited in claim 12, further comprising installing a gate, which is self-aligned in relation to the source region and electrically coupled to the gate electrode.

23. A semiconductor device product, which is formed by a production process comprising:
growing an epitaxial layer grown over a semiconductor substrate, each of which comprises a first type of dopant;
assembling a structure disposed within the epitaxial layer, the structure comprising:
a plurality of trenches, each of the trenches comprising a gate electrode and a source electrode disposed within a oxide matrix, which fills a void etched within the epitaxial layer; and
a plurality of mesas, each of which isolates a first of the plurality of trenches from a second of the plurality of trenches;
implanting a body region bridging each of the plurality of mesas, wherein the body region is disposed above the epitaxial layer and comprises a second type of dopant;
implanting, between the epitaxial layer and the body region, a region of elevated concentration of the first type of dopant at a high energy level;
implanting a source region, comprising the first type of dopant; and
installing a gate, which is self-aligned in relation to the source region and electrically coupled to the gate electrode.
